(19) United States
(12) Patent Application Publication
(10) Pub. No.: US 2008/0298024 A1
(43) Pub. Date: Dec. 4, 2008

(54) Heat spreader and method for manufacturing the same, and semiconductor device

(75) Inventors: Kouichi Takashima, Hyogo (JP); Shin-ichi Yamagata, Yamagata (JP); Osamu Suwata, Yamagata (JP)

Correspondence Address: RABIN & Berdo, PC, 1101 14TH STREET, NW, SUITE 500, WASHINGTON, DC, 20005, US

(73) Assignee: A.L.M.T. Corp., Tokyo (JP)

(21) Appl. No.: 12/155,228

(22) Filed: May 30, 2008

(30) Foreign Application Priority Data
May 31, 2007 (JP) 2007-145688
May 7, 2008 (JP) 2008-121265

(51) Int. Cl. H05K 7/20; B21C 37/00; B05D 5/12

(52) U.S. Cl. 361/718; 428/607; 427/123

(57) ABSTRACT

On a connection surface 2 of a base substrate 1 composed of a material including Cu, a heat spreader includes a Ni plating layer 3 having a high Cu region 5 where the content of Cu is not less than 1% by mass, in a range of not more than 2 μm in the thickness direction from an interface with a base substrate 1, and the content of Cu in a foremost surface 6 of the Ni plating layer 3 is less than 0.5% by mass, and the adhesion strength of the Ni plating layer 3 to the base substrate 1 is not less than 90 N/mm². A semiconductor device includes a semiconductor element, and the heat spreader for removing heat generated when the semiconductor element is operated. In a manufacturing method, a first plating layer to form the high Cu region is formed on the connection surface 2 of the base substrate 1 and heat-treated at a temperature of more than 600° C., and a second plating layer is then formed thereon and heat-treated at a temperature of not more than 600° C.

### BACKGROUND OF THE INVENTION

1. Field of the Invention

The present invention relates to a heat spreader suitably used for heat removal from a semiconductor element, a method for manufacturing the heat spreader, and a semiconductor device using the heat spreader.

2. Description of the Background Art

In order to remove heat generated when semiconductor elements are operated directly outward from the elements or indirectly through heat sinks, stems, packages, etc., heat spreaders have been used as semiconductor element mounted members called sub-mounts, lids, base substrates, etc. Heat sinks having fins or the like formed therein integrally with heat spreaders, for example, have been also used.

Conventional heat spreaders have been generally formed of Si (silicon), ceramic, etc. However, heat spreaders composed of a Cu—W composite material formed by infiltrating Cu (copper) into pores of a porous body composed of W (tungsten), a Cu—Mo composite material formed by infiltrating Cu into pores of a porous body composed of Mo (molybdenum), and so on have been proposed in recent years (see JP 06-013494 A (1994)).

The heat spreaders are formed in any solid shapes having a plurality of connection surfaces to which semiconductor elements, heat sinks, stems, and packages, etc. (they may be hereinafter generically referred to as “another members”. Furthermore, the members excluding the semiconductor elements may be generically referred to as “heat removal members”), for example, are connected. Semiconductor devices are configured by connecting the semiconductor elements to at least one of the plurality of connection surfaces and connecting the heat removal members such as the heat sinks, the stems, the packages, etc. to the other connection surfaces.

The semiconductor devices are required to have such high reliability that they can pass a high-temperature and high-humidity test in which they are left at rest for 1000 hours under a high-temperature and high-humidity environment of a temperature of +85° C. and a relative humidity of 85%, for example, or a heat cycle test in which the step of leaving them at rest for thirty minutes at a temperature of +150° C. and the step of leaving them at rest for thirty minutes at a temperature of −65° C. are taken as one cycle and this cycle is repeated through 1000 times, for example.

However, since in the heat spreaders composed of the previously described composite materials, Cu exposed to their surfaces is easily oxidized and corroded under various environments such as the high-temperature and high-humidity environment, it is difficult to provide the semiconductor devices with such high reliability required in the above-mentioned tests. Therefore, JP 06-013494 A (1994) proposes that at least a connection surface of a base substrate to form a heat spreader, formed of the above-mentioned composite material in a predetermined solid shape is subjected to Ni (nickel) plating to form a Ni plating layer having a thickness of approximately 1 μm, and the base substrate having the Ni plating layer is then heated to approximately 800° C. in a reducing atmosphere such as a hydrogen gas atmosphere, thereby to manufacture the heat spreader.

The Ni plating layer is heated in order to diffuse Cu contained in the base substrate into the Ni plating layer by utilizing the fact that Cu and Ni are wholly dissolved. This causes the Ni plating layer to be firmly integrated with the base substrate, which can inhibit the Ni plating layer from being blistered or peeled from the base substrate due to thermal hysteresis at the time when the semiconductor device is used (for example, heat generation at the time when a semiconductor element is operated).

When the Ni plating layer is heat-treated at high temperature, however, Cu in the base substrate is liable to be diffused to a foremost surface of the Ni plating layer and accumulated in a state exposed to the foremost surface. The exposed Cu is easily oxidized and corroded. Therefore, the larger the exposure amount of Cu is, the lower the resistance of the Ni plating layer to the high-temperature and high-humidity environment or the like becomes, so that the semiconductor device may not have high reliability.

Particularly in semiconductor devices assembled by bonding another members to connection surfaces of heat spreaders using resin adhesives, which tend to increase in recent years, when Cu exposed to foremost surfaces of Ni plating layers are oxidized or corroded, some serious defects may be developed. For example, the connection strengths of the another members to the heat spreaders may be reduced, or the another members may be peeled from the heat spreaders.

In order to solve such problems, it has been considered that the temperatures for heat treatments are reduced and that Au plating layers are further laminated on the Ni plating layers. In the former case, however, the whole amounts of Cu diffused into the Ni plating layers from base substrates are naturally reduced, so that adhesion of the Ni plating layers to the base substrates is lowered. Therefore, the connection strengths of the another members to the heat spreaders may be reduced contrary to the intension, or the another members, together with the Ni plating layers, may be peeled from the heat spreaders. Furthermore, in the latter case, the manufacturing costs of the heat spreaders are significantly increased.

Therefore, it is proposed that an Al (Aluminum) coating layer whose foremost surface is coated with an oxide film caused by natural oxidation of Al is formed [see JP 10-284643 A (1998)], or a diamond-like carbon film is formed [see JP 2004-104074 A], in place of the Ni plating layer, on at least a connection surface of a base substrate. However, the former Al coating layer is degraded particularly in an atmosphere including chlorine, so that adhesion to the base substrate is liable to be lowered. An Ag (silver) filler may be blended with the previously described resin adhesives in order to enhance its thermal conductivity. However, chlorine is generally blended with the resin adhesives, with which the Ag filler is blended, in order to enhance affinity between resin to form the resin adhesives and the Ag filler.

When the heat spreader having the former Al coating layer is used for the semiconductor devices assembled by bonding the another members to the connection surfaces of the heat spreaders using the resin adhesives, therefore, the Al coating layer is easily degraded by chlorine in the resin adhesives. Therefore, the connection strength of the another member to the heat spreader may be reduced contrary to the intention, or the another member, together with the Al coating layer, may be peeled from the heat spreader. Furthermore, in the latter case, the manufacturing cost of the heat spreader is significantly increased.

### SUMMARY OF THE INVENTION

An object of the present invention is to provide a heat spreader that allows high reliability to be given to a semiconductor device because the connection strength to another member is not easily reduced and the another member is not easily peeled, and a semiconductor device using the heat spreader. Another object of the present invention is to provide a method for manufacturing the heat spreader according to the present invention efficiently and with good reproducibility.

In order to solve the above-mentioned problem, the inventors have examined that in a heat spreader including a base substrate composed of the previously described material including Cu such as a Cu—W composite material, and an Ni plating layer formed on at least a connection surface of the base substrate, the content of Cu diffused from the base substrate and contained in the Ni plating layer is made to differ in concentration in the thickness direction of the Ni plating layer.

As a result, the inventors have found that when

(I) a content R_{H} (% by mass) of Cu in a range of not more than 2 μm in the thickness direction from an interface between the Ni plating layer and the base substrate on the side of the interface is set to a high concentration satisfying the following equation (1):

1% by mass≦R_{H} (1),

and
(II) Cu is not contained on a foremost surface of the Ni plating layer, or a content R_{S} (% by mass) of Cu in the foremost surface is set to a low concentration satisfying the following equation (2), so as not to expose Cu in the foremost surface of the Ni plating layer or to reduce the amount of Cu to be exposed:

0% by mass<R_{S}<0.5% by mass (2),

it is possible to inhibit the connection strength of another member to the heat spreader from being reduced and inhibit the another member from being peeled from the heat spreader due to oxidation and corrosion of the Cu by improving the resistance of the Ni plating layer to a high-temperature and high-humidity environment or the like while ensuring good adhesion of the Ni plating layer to the base substrate.

Furthermore, Ni forming the Ni plating layer and Cu contained in the Ni plating layer are difficult to be degraded by chlorine in resin adhesives, similarly to Al. Therefore, it has been also proved that there are no possibilities that the degradation causes the connection strength of the another member to the heat spreader to be reduced and causes the another member, together with the Ni plating layer, to be peeled from the heat spreader, and that there are no possibilities that the manufacturing cost of the heat spreader is increased as in a case where the heat spreader is subjected to Au plating or a diamond-like carbon film is formed therein.

Therefore, the present invention is directed to a heat spreader including a base substrate composed of a material containing at least Cu and having a connection surface for connection to another member, and a Ni plating layer formed on at least the connection surface of the base substrate, in which in a range of not more than 2 μm in a thickness direction from an interface with the base substrate, the Ni plating layer has a high Cu region where a content R_{H} (% by mass) of Cu satisfies the following equation

1% by mass≦R_{H} (1)

a foremost surface of the Ni plating layer does not contain Cu, or a content R_{S} (% by mass) of Cu in the foremost surface satisfies the following equation (2):

0% by mass<R_{S}<0.5% by mass (2),

and an adhesion strength S_{A} (N/mm²) of the Ni plating layer to the base substrate is not less than 90 N/mm².

In the heat spreader according to the present invention, it is preferable that in a range of not less than 0.3 μm in the thickness direction from the foremost surface, the Ni plating layer has a low Cu region where Cu is not contained, or a content R_{L} (% by mass) of Cu satisfies the following equation (3):

0% by mass<R_{L}<0.5% by mass (3).

To provide the low Cu region on the side of the foremost surface of the Ni plating layer makes it possible to more effectively prevent Cu from being accumulated on the foremost surface, or to reduce the amount of Cu to be accumulated, thereby to make it possible to even more effectively prevent the connection strength of the another member to the heat spreader from being reduced and prevent the another member from being peeled from the heat spreader due to oxidation and corrosion of the Cu.

It is preferable that in the Ni plating layer, the thickness of the high Cu region is not less than 0.1 μm and not more than 2 μm. The effect of maintaining good adhesion of the Ni plating layer to the base substrate by providing the high Cu region can be further improved by setting the thickness of the high Cu region in the above-mentioned range.

Although the base substrate can be composed of various materials including at least Cu, it is preferable that the base substrate is particularly composed of a Cu—W composite material and the content of W in the Cu—W composite material is not less than 75% by mass and not more than 95% by mass. The base substrate composed of the Cu—W composite material is excellent in compatibility in coefficients of thermal expansion with another members connected to the connection surface, i.e., a semiconductor element composed of various semiconductor materials and a heat sink, a stem, a package, etc. composed of Si, ceramic or the like, has high thermal conductivity, and can be manufactured at low cost.

The semiconductor device according to the present invention includes a semiconductor element, and the heat spreader according to the present invention for removing heat generated when the semiconductor element is operated. According to the present invention, the function of the heat spreader can prevent the connection strength of the another member from being reduced under various environments such as a high-temperature and high-humidity environment, and prevent the another member from being peeled, thereby to give high reliability to the semiconductor device.

An example of the specific configuration of the semiconductor device is a semiconductor device in which the heat spreader has a plurality of connection surfaces, and the semiconductor element is connected to at least one of the connection surfaces and heat removal member is connected to another connection surfaces through resin adhesive containing Ag fillers respectively. Furthermore, in the semiconductor device, it is preferable that the respective adhesive strengths indicating the connection strengths of the semiconductor element and the heat removal member to the connection surface of the heat spreader are not less than 15 N/mm².

The present invention is directed to a method for manufacturing the heat spreader of the present invention, including the steps of subjecting at least the connection surface of a base substrate composed of a material containing at least Cu to Ni plating to form a first plating layer, and heat-treating the first plating layer at a temperature T₁ (° C.) satisfying the following equation (4) to diffuse Cu into the first plating layer from the base substrate:

600° C.<T₁≦850° C. (4),

and subjecting a surface of the first plating layer to Ni plating to form a second plating layer, and heat-treating the second plating layer at a temperature T₂ (° C.) satisfying the following equation (5) to integrate the second plating layer and the first plating layer to form a Ni plating layer:

300° C.≦T₂≦600° C. (5).

In the manufacturing method according to the present invention, the heat spreader according to the present invention can be manufactured with good reproducibility and efficiently by only repeating Ni plating and heat treatment. That is, when the Ni plating layer is formed through the foregoing steps, the thickness and the content of Cu of the high Cu region can be respectively caused to substantially coincide with the thickness of the first plating layer and the content of Cu, and the thickness and the content of Cu of the low Cu region can be respectively caused to substantially coincide with the thickness and the content of Cu of the second plating layer.

Furthermore, the contents of Cu in the first and second plating layers can be respectively optionally adjusted by changing conditions, and particularly the temperatures, for heat treatment of the plating layers. Therefore, the thickness and the content of Cu of the high Cu region, the content of Cu in the foremost surface of the Ni plating layer, and the thickness and the content of Cu of the low Cu region including the foremost surface can be optionally adjusted by changing the respective thicknesses of the plating layers and the conditions for heat treatment, which allows the heat spreader according to the present invention to be manufactured with good reproducibility and efficiently.

### BRIEF DESCRIPTION OF THE DRAWINGS

FIG. 1 is a partially enlarged sectional view of a Ni plating layer as a principal part of an example of an embodiment of a heat spreader according to the present invention;

FIG. 2 is a sectional view showing an example of an embodiment of a semiconductor device according to the present invention;

FIG. 3 is a sectional view of the outline of a test piece prepared in order to measure adhesive strength in examples and comparative examples of the present invention;

FIG. 4 is a graph showing distribution curves of respective elements in the thickness direction of an Ni plating layer in a heat spreader in example 1 of the present invention;

FIG. 5 is a graph showing the distribution curve of Cu in the distribution curves shown in FIG. 4 in enlarged fashion;

FIG. 6 is a graph showing distribution curves of respective elements in the thickness direction of an Ni plating layer in a heat spreader in comparative example 1; and

FIG. 7 is a graph showing the distribution curve of Cu in the distribution curves shown in FIG. 6 in enlarged fashion.

### DESCRIPTION OF THE PREFERRED EMBODIMENTS

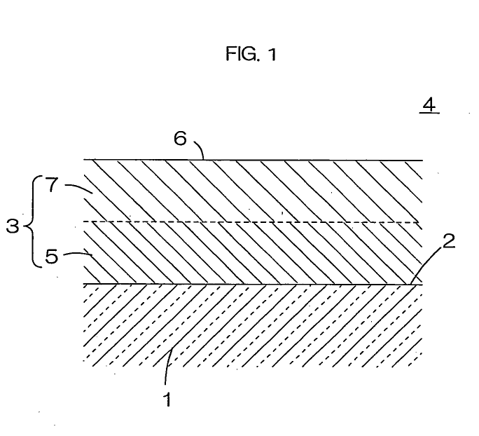

FIG. 1 is a partially enlarged sectional view of a Ni plating layer as a principal part of an example of an embodiment of a heat spreader according to the present invention.

The present invention is directed to a heat spreader 4 including a base substrate 1 composed of a material containing at least Cu and having a connection surface 2 for connection to a another member, and a Ni plating layer 3 formed on at least the connection surface 2 of the base substrate 1, in which in a range of not more than 2 μm in the thickness direction from an interface with the base substrate 1, the Ni plating layer 3 has a high Cu region 5 where the content R_{H} (% by mass) of Cu satisfies the following equation (1):

1% by mass<R_{H} (1),

its foremost surface 6 does not contain Cu, or the content R_{S} (% by mass) of Cu in the foremost surface 6 satisfies the following equation (2):

0% by mass<R_{S}<0.5% by mass (2),

and the adhesion strength S_{A} (N/mm²) of the Ni plating layer 3 to the base substrate 1 is not less than 90 N/mm².

Examples of the base substrate 1 include ones composed of Cu alone, an alloy including Cu, and a composite material including Cu. Examples of the composite material including Cu include:

(a) A Cu—W composite material or a Cu—Mo composite material respectively formed by infiltrating Cu into pores of porous bodies composed of W or Mo, previously described, and
(b) A Cu-diamond composite material having a composite structure in which a large number of minute diamond particles are combined using Cu serving as a binder.

A clad material having a laminated structure in which two or more types of layers, each composed of any one of the above-mentioned metal, alloy and composite material, are laminated can be suitably used as a material forming the base substrate 1. Examples of the clad material include:

(c) A Cu/Cu—Mo/Cu clad material obtained by respectively laminating Cu layers on both surfaces of the Cu—Mo composite material described in (a),
(d) A Cu/Mo/Cu clad material obtained by laminating a Cu layer, a Mo layer, and a Cu layer in this order, and
(e) A Cu/Cu-diamond/Cu clad material obtained by respectively laminating Cu layers on both surfaces of the Cu-diamond composite material described in (b).

It is preferable that the thermal conductivity of the base substrate 1 is not less than 170 W/m·K and not more than 650 W/m·K, and particularly not less than 200 W/m·K and not more than 650 W/m·K, considering that heat generated when the semiconductor element is operated is dissipated as smoothly as possible. When the thermal conductivity is less than the above-mentioned range, heat generated when the semiconductor element is operated is not allowed to efficiently escape. Therefore, the operating efficiency of the semiconductor device may be reduced, the life thereof may be shortened, or the semiconductor element may be damaged before the end of the life. On the other hand, when the thermal conductivity of the base substrate 1 exceeds the above-mentioned range, the base substrate 1 is difficult to be produced from a material including Cu.

It is preferable that the coefficient of thermal expansion of the base substrate 1 is not less than 2.0×10⁻⁶/K and not more than 10×10⁻⁶/K, considering that compatibility in coefficients of thermal expansion with semiconductor elements composed of various semiconductor materials, and a heat sink, a stem, a package, etc. composed of Si, ceramic, or the like. When the coefficient of thermal expansion of the base substrate 1 is less than the above-mentioned range or exceeds the above-mentioned range, the compatibility in coefficients of thermal expansion is lowered. Therefore, an excessive stress is created in the semiconductor element due to thermal hysteresis or the like at the time when the another member is connected to the connection surface 2 of the heat spreader 4 and when the semiconductor device is used, so that the characteristics of the semiconductor element may be degraded and the semiconductor element may be damaged.

Furthermore, the connection strength of the another member, such as the semiconductor element, to the heat spreader 4 may be reduced, or the another member may be peeled from the heat spreader 4. Note that when the semiconductor element is composed of an Si-based, GaAs (gallium-arsenic)-based, or GaN (gallium nitride)-based semiconductor material, it is further preferable that the coefficient of thermal expansion of the base substrate 1 is not less than 4.0×10⁻⁶/K and not more than 8.0×10⁻⁶/K in the above-mentioned range, considering that the compatibility in coefficients of thermal expansion with the semiconductor element is further improved.

In recent years, an attempt for the heat spreader 4 itself to function as an electrode for electrical connection to the semiconductor element has been made. For that purpose, it is preferable that the specific resistance of the base substrate 1 is not less than 1.6×10⁻⁸ Ωm and not more than 1.0×10⁻³ Ωm. When the specific resistance of the base substrate 1 exceeds the above-mentioned range, it is not only impossible to sufficiently obtain the effect of causing the heat spreader 4 itself to function as the electrode, but is also possible that the base substrate 1 itself generates heat when the heat spreader 4 is caused to function as the electrode. A material having a specific resistance of less than the above-mentioned range (including a composite material) is limited to a special material, is high in cost, and is not easy to manufacture. This causes the productivities of the base substrate 1, and thus the heat spreader 4 and the semiconductor device, to be lowered, to constitute a factor that increases the manufacturing cost.

In order to adjust all of the characteristics in the suitable ranges, in the case of the base substrate 1 composed of the alloy, for example, the composition thereof may be adjusted. In the case of the base substrate 1 composed of the composite material, the composite structure and the composition thereof may be adjusted. In the case of the base substrate 1 composed of the clad material, the composite structure thereof and the thickness of each of layers may be adjusted. Such adjustments allow the base substrate 1 whose characteristics respectively satisfy the above-mentioned ranges to be formed. Examples of a material for the base substrate 1 suitable from the viewpoint of the thermal conductivity and the coefficient of thermal expansion include the Cu—W composite material and the Cu—Mo composite material described in (a), and the Cu-diamond composite material described in (b). Particularly, the Cu—W composite material in (a) is preferable from the viewpoint of the manufacturing cost. Note that the ratio of diamond in the Cu-diamond composite material in (b) is preferably not less than 40% by mass and not more than 60% by mass.

Furthermore, it is preferable that the ratio of W in the Cu—W composite material in (a) is not less than 75% by mass and not more than 95% by mass, and particularly not less than 80% by mass and not more than 90% by mass. When the ratio of W is less than the above-mentioned range, the coefficient of thermal expansion of the base substrate 1 composed of the Cu—W composite material exceeds the above-mentioned range. Therefore, the compatibility in coefficient of thermal expansion with the another members connected to the connection surface 2, that is, the semiconductor elements composed of various semiconductor materials, and the heat sink, the stem, the package, etc. composed of Si, ceramic or the like may not be ensured.

When the ratio of W exceeds the above-mentioned range, the thermal conductivity of the base substrate 1 composed of the Cu—W composite material is less than the above-mentioned range, so that heat generated when the semiconductor element is operated is not allowed to efficiently escape. Therefore, the operating efficiency of the semiconductor element may be reduced, the life thereof may be shortened, or the semiconductor element may be damaged before the end of the life. The base substrate 1 composed of the Cu—W composite material can be manufactured by a manufacturing method disclosed in JP 06-013494 A (1994).

Specifically, powder of W is mixed with powder of a W alloy having a small amount of Ni functioning as a binder, a resin binder, or the like, as required, is press molded to a predetermined solid shape, and is then sintered in a reducing atmosphere to produce a porous body composed of W, and Cu melted by being heated is infiltrated into pores of the porous body in the reducing atmosphere, to obtain a precursor of the base substrate 1 composed of the Cu—W composite material. The precursor is cut out to a predetermined solid shape of the base substrate 1 by wire electrical discharge machining or the like, as required, and its connection surface 2 is finished so as to have predetermined surface roughness, thereby to manufacture the base substrate 1.

It is preferable that the surface roughness of the connection surface 2 is not more than 1.6 μm when it is expressed in arithmetic average roughness Ra of a roughness curve defined in Japanese Industrial Standard (JIS) B0601:2001 “Geometrical Product Specifications (GPS)—Surface texture: Profile method—Terms, definitions and surface texture parameters” (ISO 4287:1997 (IDT (IDENTICAL))]. When the arithmetic average roughness Ra exceeds the above-mentioned range, good thermal conduction may not be obtained between the connection surface 2 and the another member connected thereto.

Although the shape and the like of the base substrate 1 can be optionally set in conformity with the shape and the size of the semiconductor element connected to the connection surface 2, or the whole shape and the like of the semiconductor device configured by connecting the another members such as semiconductor elements, the heat sink, the stem, the package, etc. to the connection surface 2, for example, it is preferable that in the case of the base substrate 1 in the shape of a plane, for example, the thickness thereof is not less than 0.15 mm and not more than 10 mm, and particularly not less than 1 mm and not more than 3 mm. When the thickness exceeds the above-mentioned range, the semiconductor device is difficult to be made thin and miniaturized, and the material cost thereof piles up, which also causes the manufacturing costs of the heat spreader 4 and thus the semiconductor device to be increased.

On the other hand, when the thickness is less than the above-mentioned range, the base substrate 1 easily warps. Therefore, the another member such as the semiconductor element may not be able to satisfactorily adhere to the connection surface 2. Furthermore, the heat capacity of the heat spreader 4 is insufficient, so that sufficient heat dissipation properties may not be obtained. In the case of the base substrate 1 whose plane shape is rectangular, for example, it is preferable that the warping amount of the base substrate 1 is not more than 1 μm, and particularly not more than 0.5 μm, per millimeter in length in its diagonal direction. When the warping amount exceeds the above-mentioned range, the another member such as the semiconductor element may not be able to satisfactorily adhere to the connection surface 2, as described above.

Therefore, heat generated when the semiconductor element is operated is not allowed to efficiently escape. Then, the operating efficiency of the semiconductor element may be reduced, the life thereof may be shortened, and the semiconductor element may be damaged before the end of the life. Note that it is most preferable that the minimum value of the warping amount is 0 μm per millimeter in length in the diagonal direction, i.e., there is no warping. The shape of the base substrate 1 is not limited to the above-mentioned plane shape. For example, the base substrate 1 can be formed in any solid shape such as a concave shape having a recess accommodating a semiconductor element on one surface of the plane, as disclosed in JP 2004-104074 A, for example.

It is required that the Ni plating layer 3 formed on at least the connection surface 2 of the base substrate 1 has, as described above, in a range of not more than 2 μm in the thickness direction from an interface with the base substrate 1, a high Cu region 5 where the content R_{H} (% by mass) of Cu satisfies the following equation (1):

1% by mass≦R_{H} (1)

its foremost surface 6 does not contain Cu, or the content R_{S} (% by mass) of Cu in the foremost surface 6 satisfies the following equation (2):

0% by mass<R_{S}<0.5% by mass (2),

and the adhesion strength S_{A} (N/mm²) of the Ni plating layer 3 to the base substrate 1 is not less than 90 N/mm². This allows the resistance of the Ni plating layer 3 to a high-temperature and high-humidity environment or the like to be improved by reducing the amount of Cu exposed to the foremost surface of the Ni plating layer 3 while ensuring good adhesion of the Ni plating layer 3 to the base substrate 1. Therefore, it is possible to suppress the connection strength of the another member to the heat spreader 4 from being reduced and suppress the another member from being peeled from the heat spreader 4 due to oxidation and corrosion of the Cu.

The reason why the thickness of the high Cu region 5 is limited to not more than 2 μm is that when the thickness exceeds 2 μm, the Ni plating layer 3 cannot be brought into a state where the foremost surface 6 thereof does not contain Cu or the content R_{S} thereof satisfies the equation (2) by inhibiting Cu from being diffused from the high Cu region 5, although it depends on the thickness of the whole Ni plating layer 3. That is, when the thickness of the high Cu region 5 exceeds 2 μm, the effect of improving the resistance of the Ni plating layer 3 to the high-temperature and high-humidity environment or the like cannot be obtained.

Note that it is preferable that the thickness of the high Cu region 5 is not less than 0.1 μm and not more than 2 μm, and particularly not less than 0.1 μm and not more than 1.5 μm, in the above-mentioned range. The effect of maintaining good adhesion of the Ni plating layer 3 to the base substrate 1 by providing the high Cu region 5 can be further improved by setting the thickness of the high Cu region 5 in the above-mentioned range.

The reason why the content R_{H} of Cu in the high Cu region 5 is limited to the range satisfying the equation (1) is that when the content R_{H} is less than 1% by mass, Cu is not sufficiently diffused from the base substrate 1 to the high Cu region 5, so that the effect of ensuring good adhesion of the Ni plating layer 3 to the base substrate 1, that is, the effect of setting the adhesion strength S_{A} (N/mm²) of the Ni plating layer 3 to the base substrate 1 to not less than 90 N/mm², cannot be obtained.

It is preferable that the content R_{H} is not more than 20% by mass. When the content R_{H} exceeds 20% by mass, the Ni plating layer 3 may not be brought into a state where the foremost surface 6 thereof does not contain Cu or the content R_{S} thereof satisfies the equation (2) by inhibiting Cu from being diffused from the high Cu region 5, although it depends on the thickness of the whole Ni plating layer 3. That is, also when the content R_{H} of Cu in the high Cu region 5 exceeds 20% by mass, the effect of improving the resistance of the Ni plating layer 3 to the high-temperature and high-humidity environment or the like may not be obtained. Note that it is more preferable that the content R_{H} is not more than 7% by mass in the above-mentioned range.

The reason why the content R_{S} of Cu in the foremost surface 6 of the Ni plating layer 3 is limited to the range satisfying the equation (2) is that when the content R_{S} is not less than 0.5% by mass, the effect of improving the resistance of the Ni plating layer 3 to the high-temperature and high-humidity environment or the like cannot be obtained. Note that it is most preferable that the foremost surface 6 does not contain Cu, that is, the content R_{S} is 0% by mass, considering the effect of improving the resistance of the Ni plating layer 3. In the present invention, the content R_{S} includes a range from less than 0.5% by mass to 0% by mass.

It can safely be said that the foremost surface 6 of the Ni plating layer 3 contains Cu in the range satisfying the equation (2), considering balance with the effect of ensuring good adhesion of the Ni plating layer 3 to the base substrate 1.

The reason why the adhesion strength S_{A} (N/mm²) of the Ni plating layer 3 to the base substrate 1 is limited to not less than 90 N/mm² is that when the adhesion strength S_{A} is less than 90 N/mm², good adhesion of the Ni plating layer 3 to the base substrate 1 cannot be ensured. That is, when the adhesion strength S_{A} is less than 90 N/mm², the Ni plating layer 3 is easily blistered or peeled from the base substrate 1 due to thermal hysteresis or the like at the time when the another member is connected to the connection surface 2 of the heat spreader 4 and when the semiconductor device is used.

The higher the adhesion strength S_{A} is, the more preferable it is. The upper limit thereof is not particularly limited. However, it is preferable that the adhesion strength S_{A} (N/mm²) is not more than 900 N/mm², considering that the heat spreader 4 including the Ni plating layer 3 having practical adhesion strength is manufactured with good productivity.

It is preferable that in a range of not less than 0.3 μm in the thickness direction from the foremost surface 6, the Ni plating layer 3 has a low Cu region 7 where Cu is not contained or the content R_{L} (% by mass) thereof satisfies the following equation (3), as also previously described:

0% by mass<R_{L}<0.5% by mass (3).

The low Cu region 7 is provided on the side of the foremost surface 6 of the Ni plating layer 3, to further reduce the amount of Cu accumulated on the foremost surface 6, which can more effectively prevent the connection strength of the another member to the heat spreader 4 from being reduced and prevent the another member from being peeled from the heat spreader 4 due to oxidation and corrosion of the Cu.

The reason why the thickness of the low Cu region is preferably not less than 0.3 μm is that when the thickness is less than 0.3 μm, the effect produced by providing the low Cu region 7 may not be sufficiently obtained depending on the thickness of the high Cu region 5, the content R_{H} of Cu, or the like. The upper limit of the thickness of the low Cu region 7 is not particularly limited. However, it is preferably 4.5 μm. When the thickness exceeds 4.5 μm, a further effect is not obtained. Moreover, the thickness of the whole Ni plating layer 3 is increased, so that a residual stress is increased. Therefore, the Ni plating layer 3 may be easily blistered or peeled from the base substrate 1 due to thermal hysteresis or the like at the time when the another member is connected to the connection surface 2 of the heat spreader 4 and when the semiconductor device is used.

The reason why the content R_{L} of Cu in the low Cu region 7 is preferably in the range satisfying the equation (3) is that when the content R_{L} is not less than 0.5% by mass, the effect produced by providing the low Cu region 7 may not be sufficiently obtained depending on the thickness of the high Cu region 5, the content R_{H} of Cu thereof, or the like. Note that it is most preferable that the low Cu region 7 does not contain Cu, that is, the content R_{L} is 0% by mass, considering the effect of improving the resistance of the Ni plating layer 3. In the present invention, the content R_{L} includes a range from less than 0.5% by mass to 0% by mass.

It can safely be said that the low Cu region 7 contains Cu in the range satisfying the equation (3), considering balance with the effect of ensuring good adhesion of the Ni plating layer 3 to the base substrate 1.

Although the high Cu region 5 and the low Cu region 7 are brought into direct contact with each other in FIG. 1, an intermediate layer that satisfies neither of the conditions imposed on the regions 5 and 7 may be interposed between the regions.

The distribution in the thickness direction of the content of Cu contained in the Ni plating layer 3 is represented by values measured using a Marcus-type RF Glow Discharge Optical Emission Spectrometer [JY5000RF-PSS manufactured by HORIBA JOBIN YVON S.A.S.].

The spectrometer repeats elemental analysis for each predetermined thickness while cutting a measurement sample in the thickness direction from its foremost surface by argon plasma. The spectrometer allows elemental analysis of the measurement sample with good resolution in a range from the foremost surface to a depth of several tens micrometers, and can obtain more average information relating to the measurement sample by reducing the effect of segregation or the like because the analysis area is as wide as 4 mmø.

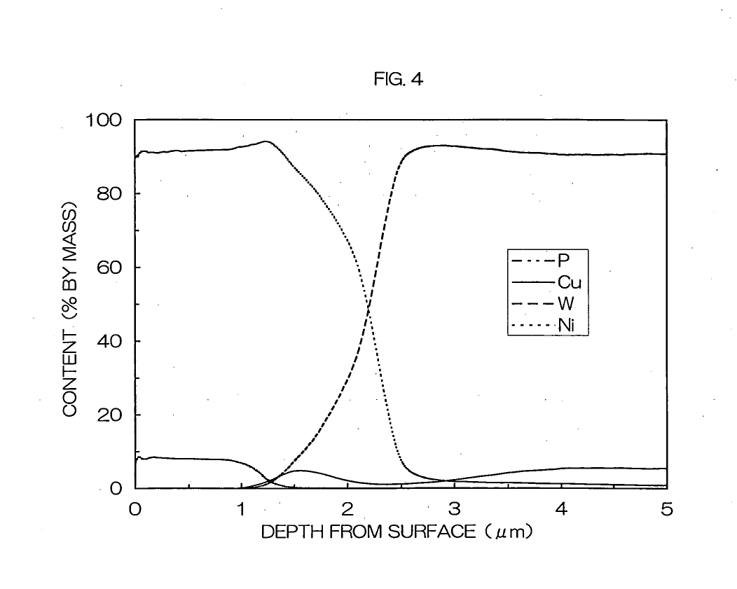

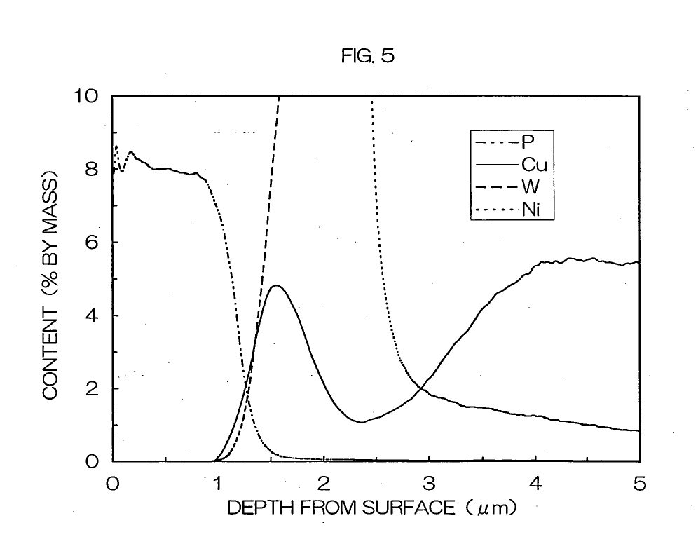

In the present invention, results obtained by subjecting the measurement sample to elemental analysis for each thickness of approximately 0.003 μm while cutting the measurement sample in the thickness direction from the foremost surface by argon plasma using the above-mentioned spectrometer are plotted as shown in FIGS. 4 and 5, for example, to find distribution curves of the contents in the thickness direction of respective elements such as Cu contained in the sample. FIG. 5 is a graph showing the distribution curve of Cu in the distribution curves shown in FIG. 4 in enlarged fashion.

Then, the content R_{S} (% by mass) of Cu in the foremost surface of the measurement sample, i.e., the foremost surface of the Ni plating layer 3, is obtained from the distribution curve, and a point at which the content of Ni that is a main component of the Ni plating layer 3 and the content of W that is a main component of the Cu—W composite material in the case illustrated, as the base substrate 1, coincide with each other is referred to as an interface between the base substrate 1 and the Ni plating layer 3.

The thickness of a region where the content R_{H} (% by mass) of Cu is not less than 1% by mass and not more than 20% by mass in the thickness direction of the Ni plating layer 3 is found from the interface toward the foremost surface 6 of the Ni plating layer 3 and is taken as the thickness of the high Cu region 5, and the thickness of a region where the content R_{L} (% by mass) of Cu is less than 0.5% by mass in the thickness direction of the Ni plating layer 3 is found from the foremost surface 6 to the base substrate 1 and is taken as the thickness of the low Cu region 7.

The adhesion strength S_{A} (N/mm²) of the Ni plating layer 3 to the base substrate 1 shall be represented by values measured by the following measuring method in which a testing method defined in JIS K6850:1999 “Adhesives-Determination of tensile lap-shear strength of rigid-to-rigid bonded assemblies” [ISO 4587:1995 (ADP (ADOPTION))] is applied.

That is, two heat spreaders in the shape of a rectangular plane are prepared, and are solder-joined, with a range of 12.5 mm in the length direction from one end on the side of the short side of a rectangle of each of the heat spreaders taken as a solder joint, under conditions of 220° C. for three minutes using a Pb—Sn eutectic solder (Pb: 60% by mass, Sn: 40% by mass), to prepare a test piece. Then, a breaking stress (N/mm²) in respectively holding two unbonded portions, which project in opposite directions, of the test piece in grippers of a precision universal tester (Autograph) and pulling the unbonded portions in opposite directions at a speed of 50 mm per minute while taking care that the center line in the width direction of the test piece and the center line of the gripper coincide with each other is taken as adhesion strength S_{A} (N/mm²) of the Ni plating layer 3 to the base substrate 1.

For example, in a case where the Ni plating layer 3 is formed by laminating a first plating layer to form the high Cu region and a second plating layer to form the low Cu region, and where both the plating layers are not sufficiently integrated with each other from reasons such as insufficient heat treatment after formation of the second plating layer, when the above-mentioned measurement is made, the Ni plating layer 3 may, in some cases, be peeled in not the interface between the Ni plating layer 3 and the bas substrate 1 but an interface between both the plating layers. The adhesion strength measured in the case is not strictly the adhesion strength of the whole Ni plating layer 3 to the base substrate 1 but adhesion strength between both the plating layers in the interface.

However, both the adhesion strengths are obtained by the same measurement and are difficult to be distinguished from each other. Moreover, peeling in the interface between both the plating layers causes the same results as those in a case where the whole Ni plating layer 3 is peeled from the base substrate 1. Therefore, it is considered that the Ni plating layer 3 having a two-layer structure must be not only excellent in adhesion strength to the base substrate 1 but also excellent in adhesion in the interface between the first plating layer and the second plating layer. Therefore, the adhesion strength S_{A} (N/mm²) of the Ni plating layer 3 to the base substrate 1, which is referred to in the present invention, shall include adhesion strength measured by the peeling in the interface.

It is preferable that the thickness of the whole Ni plating layer 3 is not more than 5 μm, and particularly not less than 0.6 μm and not more than 5 μm. When the thickness exceeds 5 μm, a residual stress is increased. Therefore, the Ni plating layer 3 may be easily blistered or peeled from the base substrate 1 due to thermal hysteresis or the like at the time when the another member is connected to the connection surface 2 of the heat spreader 4 and when the semiconductor device is used. On the other hand, when the thickness is less than 0.6 μm, it is practically difficult to form the Ni plating layer 3 which includes the high Cu region 5, and at the same time in which the content R_{S} of Cu in the foremost surface 6 is less than 0.5% by mass.

The heat spreader 4 according to the present invention including the Ni plating layer 3 can be manufactured by a manufacturing method according to the present invention including the steps of:

(i) subjecting at least the connection surface 2 of the base substrate 1 composed of a material containing at least Cu to Ni plating to form a first plating layer, and heat-treating the first plating layer at a temperature T₁ (° C.) satisfying the following equation (4) to diffuse Cu into the first plating layer from the base substrate 1:

600° C.<T₁≦850° C. (4),

and (ii) subjecting a surface of the first plating layer to Ni plating to form a second plating layer, and heat-treating the second plating layer at a temperature T₂ (° C.) satisfying the following equation (5) to integrate the second plating layer and the first plating layer to form an Ni plating layer:

300° C.≦T₂≦600° C. (5).

That is, the first plating layer formed so as to come into direct contact with at least the connection surface 2 of the base substrate 1 is heat-treated at the temperature T₁ (° C.), and Cu is diffused into the first plating layer from the base substrate 1 in the step (i), and the second plating layer laminated on the first plating layer is then heat-treated at the temperature T₂ (° C.) and integrated with the first plating layer in the step (ii).

This causes the Ni plating layer 3 to be formed in which a range substantially corresponding to the thickness of the first plating layer from the interface with the base substrate 1 serves as a high Cu region 5, and a range substantially corresponding to the thickness of the second plating layer serves as a low Cu region 7 including the foremost surface 6.

Furthermore, the content of Cu in each of the first and second plating layers can be optionally adjusted by respectively changing the temperatures T₁ and T₂ for heat treatment of the plating layers in the above-mentioned ranges. According to the above-mentioned manufacturing method, therefore, the thickness and the content R_{H} (% by mass) of Cu of the high Cu region 5, the content R_{S} (% by mass) of Cu in the foremost surface 6 of the Ni plating layer 3, and the thickness and the content R_{L} (% by mass) of Cu of the low Cu region 7 including the foremost surface 6 can be adjusted optionally and with good reproducibility by changing the respective thicknesses of the first and second plating layers and the respective conditions for heat treatment of the first and second plating layers. Therefore, the heat spreader 4 according to the present invention can be manufactured with good reproducibility and efficiently by repeating the Ni plating and the heat treatment.

In the above-mentioned manufacturing method, it is preferable that the formation and the heat treatment of the first plating layer in the step (i) and the formation and the heat treatment of the second plating layer in the step (ii) are respectively performed once in view of reducing the number of steps to reduce the manufacturing cost. However, the respective steps may be repeatedly carried out in twice or more devided in this thickness direction. In this case, the distribution of the content of Cu in the thickness direction of the Ni plating layer can be more finely controlled by individually changing the thickness of each of the layers and the conditions for heat treatment.

As the Ni plating for forming the first and second plating layers, any of Ni electroplating, electroless Ni plating and vapor deposition (including physical vapor deposition and chemical vapor deposition) may be employed. The electroless Ni plating may be:

(a) electroless Ni—P plating using sodium hypophosphite [NaH₂PO₂, etc.] as a reducing agent,

(b) electroless Ni—B plating using a boron hydride compound [NaBH₄, (CH₃)₂HN.BH₃, (C₂H₅)₂HN.BH₃, etc.] as a reducing agent, or

(c) narrowly-defined electroless Ni plating using a hydrazine compound [N₂H₄, N₂H₄—H₂SO₄, N₂H₄—HCl, N₂H₄.2HCl, etc.] as a reducing agent.

Note that it is preferable that the content of P contained in the Ni plating layer formed by the electroless Ni—P plating in (a) is not less than 6% by mass and not more than 15% by mass, and particularly not less than 9% by mass and not more than 12% by mass. Furthermore, it is preferable that the content of B contained in the Ni plating layer formed by the electroless Ni—B plating in (b) is not less than 0.1% by mass and not more than 5% by mass, and particularly not less than 0.3% by mass and not more than 3% by mass.

It is preferable that the first plating layer is formed by the Ni electroplating or the electroless Ni—B plating in (b). Since the plating layer formed by the Ni electroplating is substantially composed of pure Ni, the plating layer can be more firmly integrated with the base substrate 1 by the diffusing of Cu from the base substrate 1. Furthermore, the plating layer formed by the electroless Ni—B plating is superior in uniformity and denseness to the plating layer formed by the Ni electroplating.

It is preferable that the thickness of the first plating layer is not less than 0.1 μm and not more than 2 μm. When the thickness is less than 0.1 μm, the high Cu region having a sufficient thickness cannot be formed in the Ni plating layer 3. Therefore, the adhesion strength of the Ni plating layer 3 to the base substrate 1 may be significantly reduced. The Ni plating layer 3 may be easily blistered or peeled from the base substrate 1 due to thermal hysteresis or the like at the time when the another member is connected to the connection surface 2 of the heat spreader 4 and when the semiconductor device is used.

When the thickness exceeds 2 μm, a residual stress is easily increased, or a thermal stress caused by the difference in coefficients of thermal expansion between the base substrate 1 and the first plating layer is easily increased. Therefore, the first plating layer may be easily blistered or peeled from the base substrate 1 during the heat treatment at the temperature T₁ in the step (i).

Since the second plating layer forms the foremost surface 6 of the Ni plating layer 3, it may be formed by selecting the most suitable Ni plating method depending on the another member connected to the foremost surface 6, compatibility with resin adhesive or the like used for connecting the another member to the foremost surface 6, required characteristics, and so on. When the another member is connected to the foremost surface 6 using the previously described resin adhesive including an Ag filler and chlorine, for example, it is preferable that the second plating layer is formed by the electroless Ni—P plating. Since the Ni—P plating layer produces Ni₃P when heat-treated, and the Ni₃P is satisfactorily coupled to the Ag filler and a chlorine ion in the resin adhesive, connection reliability can be improved.

It is preferable that the thickness of the second plating layer is not less than 0.5 μm. When the thickness is less than 0.5 μm, the amount of Cu diffused into the second plating layer from the first plating layer is too large during heat treatment at the temperature T₂ in the step (ii). Therefore, it may be impossible to suppress the content R_{S} (% by mass) of Cu in the foremost surface 6 of the Ni plating layer 3 to the content satisfying the equation (2), and to form the low Cu region having the predetermined thickness in the Ni plating layer 3.

The upper limit of the thickness of the second plating layer is not particularly limited. However, it is preferably not more than 4.5 μm. Even when the thickness exceeds 4.5 μm, a further effect is not obtained. Moreover, the thickness of the whole Ni plating layer 3 is increased, and a residual stress is increased. Therefore, the Ni plating layer 3 may be easily blistered or peeled from the base substrate 1 due to thermal hysteresis or the like at the time when the another member is connected to the connection surface 2 of the heat spreader 4 and when the semiconductor device is used.

As previously described, the reason why the temperature T₁ (° C.) for heat treatment of the first plating layer is set to a temperature satisfying the equation (4) is that when the temperature T₁ is not more than 600° C., good adhesion of the Ni plating layer 3 to the base substrate 1 cannot be ensured by diffusing a sufficient amount of Cu into the first plating layer from the base substrate 1. On the other hand, when the temperature exceeds 850° C., the amount of Cu diffused into the first plating layer is too large, so that good adhesion of the Ni plating layer 3 to the base substrate 1 cannot be ensured contrary to the intension. Moreover, a thermal stress caused by the difference in coefficients of thermal expansion between the base substrate 1 and the first plating layer is increased, so that the first plating layer may be easily blistered and peeled from the base substrate 1 during the heat treatment at the temperature T₁.

The reason why the temperature T₂ for heat treatment of the second plating layer is set to a temperature satisfying the equation (5) is that when the temperature is less than 300° C., the first and second plating layers cannot be satisfactorily integrated with each other. On the other hand, when the temperature exceeds 600° C., the amount of Cu diffused into the second plating layer from the first plating layer is too large, so that the content R_{S} (% by mass) of Cu in the foremost surface 6 of the Ni plating layer 3 cannot be suppressed to the content satisfying the equation (2).

The semiconductor device according to the present invention includes a semiconductor element, and the heat spreader according to the present invention for removing heat generated when the semiconductor element is operated. An example of the specific configuration of the semiconductor device is one in which the heat spreader has a plurality of connection surfaces, and the semiconductor element is connected to at least one of the connection surfaces and heat removal member is connected to another connection surface through resin adhesive containing Ag fillers respectively.

In the semiconductor device, it is preferable that initial adhesive strength S_{B} (N/mm²) indicating the connection strength of the another member to the connection surface of the heat spreader is not less than 15 N/mm², considering that the semiconductor device is given high reliability by further reliably preventing the connection strength of the another member to the heat spreader from being reduced or preventing the another member from being peeled from the heat spreader due to thermal hysteresis or the like at the time when the another member is connected to the connection surface of the heat spreader and when the semiconductor device is used. Furthermore, it is preferable that the adhesive strength S_{B} (N/mm²) after a high-temperature and high-humidity test, in which the semiconductor device is left at rest for 1000 hours under a high-temperature and high-humidity environment of a temperature of +85° C. and a relative humidity of 85%, is not less than 5 N/mm².

The adhesive strength S_{B} (N/mm²) shall be represented by adhesive strength measured by a testing method defined in JIS K6850:1999 “Adhesives-Determination of tensile lap-shear strength of rigid-to-rigid bonded assemblies”. At the time of the measurement, resin adhesive used for actually connecting the another member to the connection surface of the heat spreader shall be used. The higher the adhesive strength S_{B} (N/mm²) is the more preferable it is both at the beginning and after the high-temperature and high-humidity test. The upper limit thereof may reach a measurement limit in the above-mentioned measurement method, that is, the adhesive strength of the resin adhesive used for the measurement, or the breaking strength of the another member such as the semiconductor element itself, for example.

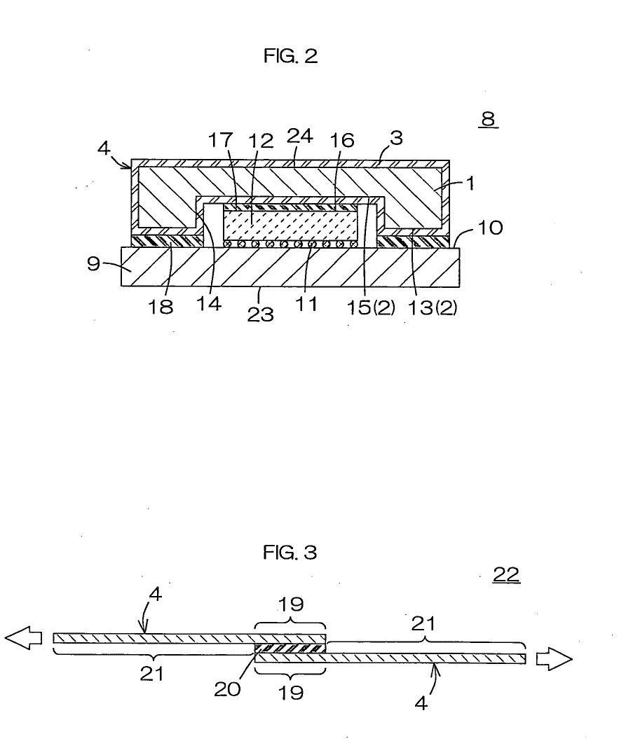

FIG. 2 is a sectional view showing an example of an embodiment of a semiconductor device according to the present invention. The semiconductor device 8 in the illustrated example includes a plane-shaped package 9, a plane-shaped semiconductor element 12 connected to the center of a surface 10 (on the upper side in the drawing) of the package 9 through a solder bump 11, and the heat spreader 4 according to the present invention.

The heat spreader 4 includes a base substrate 1 which is in the shape of a plane as a whole, as previously described, in the illustrated example, and which is formed in a concave shape provided with a recess 14 for accommodating the semiconductor element 12 at the center of a surface 13 (on the lower side in the drawing) of the plane. A bottom surface 15 of the recess 14 in the base substrate 1 serves as a connection surface 2 for connection to the semiconductor element 12, the surface 13 surrounding the recess 14 serves as a connection surface 2 for connection to the package 9, and a Ni plating layer 3 having a content of Cu distributed in the thickness direction as previously described on the whole of its outer peripheral surface in the illustrated example, thereby to configure the heat spreader 4.

The heat spreader 4 is made to adhere to and fixed to the package 9 and the semiconductor element 12 with a resin adhesive layer 17 sandwiched between the Ni plating layer 3 on the connection surface 15 and a surface 16 (on the upper side in the drawing) of the semiconductor element 12 and with a resin adhesive layer 18 sandwiched between the Ni plating layer 3 on the connection surface 13 and the surface 10 on the upper side of the package 9, thereby to configure the semiconductor device 8. In the semiconductor device 8, heat generated when the semiconductor element 12 is operated can be dissipated directly through the heat spreader 4 or indirectly through the heat spreader 4 and the package 9.

Moreover, the semiconductor element 12 is protected from the exterior by the package 9 and the heat spreader 4. Therefore, the stability of the operation of the semiconductor element 12, the reliability of the semiconductor device 8, and so on can be improved, combined with the fact that the heat spreader 4 has the previously described configuration according to the present invention. The configuration of the semiconductor device is not limited to that in the illustrated example. For example, various configurations such as a configuration in which a semiconductor element is connected to one surface and a heat sink, a stem, a package or the like are connected to the opposite surface of a plane-shaped heat spreader can be employed.

### EXAMPLES

### Example 1

### Production of Base Substrate

1% by mass of an acrylic binder was added to W powder having an average particle diameter of 3 μm, to granulate the powder to obtain a granulated body having an average particle diameter of 50 μm. A recess, whose plane shape was a rectangle having dimensions of 30 mm in width by 110 mm in length, of a metal mold was filled with the granulated body, and the granulated body was press-molded to the shape of a rectangular plane under a surface pressure of 1.5 ton/cm², and was then heated for one hour at a temperature of 800° C. in a hydrogen gas atmosphere to remove the binder, and was then successively heated to 1250° C. in the hydrogen gas atmosphere and was sintered, to produce a porous body composed of W.

The porous body was then heated to 1250° C. in the hydrogen gas atmosphere, with the porous body overlapped with a Cu plate whose volume was 1.3 times of the porosity of the porous body, to dissolve Cu, to infiltrate the Cu into pores of the porous body composed of W to obtain a precursor of a base substrate composed of a Cu—W composite material (Cu: 10% by mass, W: 90% by mass). Two surfaces (connection surfaces), parallel to each other, of a plate of the precursor and four side surfaces thereof crossing the two surfaces were respectively ground, to produce a base substrate in the shape of a rectangular plane having dimensions of 25 mm in width by 100 mm in length by 2 mm in thickness.

(Manufacture of Heat Spreader)

After a first plating layer having a thickness of 1.2 μm was formed by Ni electroplating on the whole surface of the base substrate, and was heated to 800° C. in a hydrogen gas atmosphere and heat-treated, a second plating layer having a thickness of 1 μm was formed by electroless Ni—P plating on the first plating layer, and was heated to 500° C. in a hydrogen gas atmosphere and heat-treated to form an Ni plating layer, thereby to manufacture a heat spreader.

(Measurement of Distribution of Content of Cu or the Like)

As to the Ni plating layer in the heat spreader, the distribution in the thickness direction of the content of each of elements such as Cu was measured using the above-mentioned Marcus-type RF Glow Discharge Optical Emission Spectrometer [JY5000RF-PSS manufactured by HORIBA JOBIN YVON S.A.S.]. The measurement was made by plotting results obtained by subjecting a measurement sample to elemental analysis for each thickness of approximately 0.003 μm while cutting the measurement sample in the thickness direction from its foremost surface by argon plasma. The results are shown in FIG. 4. FIG. 5 illustrates the distribution curve of Cu in the distribution curves shown in FIG. 4 in enlarged fashion.

It was confirmed from FIGS. 4 and 5 that in the Ni plating layer, a range of 1 μm in the thickness direction from an interface with a base substrate (a point at which the content of Ni and the content of W coincide with each other) toward its foremost surface (a point at a depth of 0 μm from its surface) was a high Cu region where the content R_{H} (% by mass) of Cu was within the range expressed by the equation (1) and the maximum content of Cu 4.8% by mass, the content R_{S} (% by mass) of Cu on the foremost surface of the Ni plating layer was less than 0.01% by mass (a measurement limit), and a range of 1.1 μm in the thickness direction from the foremost surface of the Ni plating layer toward the base substrate was a low Cu region where the content of R_{L} (% by mass) of Cu was within the range expressed by the equation (3).

(Measurement of Adhesive Strength)

The adhesive strength indicating the connection strength of another member to a connection surface of the heat spreader was measured in conformity with a testing method defined in JIS K6850:1999 “Adhesives-Determination of tensile lap-shear strength of rigid-to-rigid bonded assemblies”. That is, as shown in FIG. 3, the two heat spreaders 4, described above, were prepared, were overlapped with each other, with a range of 12.5 mm in the length direction from one end on the short side of each of the two heat spreaders 4 serving as an adhesive portion 19, such that unbonded portions 21 in the heat spreaders 4 respectively project in opposite directions from the adhesive portions 19 through a layer 20 made of liquid epoxy resin adhesive containing 70% by mass of an Ag filler, the two heat spreaders 4 were heated for one hour at a temperature of 180° C. to cure the adhesive, and were further dried for 24 hours at a temperature of 150° C., to produce a test piece 22 for adhesion strength measurement.

A breaking stress (N/mm²) measured by respectively holding the two unbonded portions 21 of the test piece 22 which project in opposite directions in grippers of a precision universal tester (Autograph) (not shown) and pulling the unbonded portions 21 in opposite directions, as shown by illustrated hollow arrows, at a speed of 50 mm per minute while taking care so that the center line in the width direction of the test piece 22 and the center line of the grippers coincide with one another was 17.6 N/mm² when it was measured as initial adhesive strength. Therefore, it was confirmed that the heat spreader in the example 1 was superior in the connection strength to the another member.

Further, after a test piece 22 produced in the same manner was left at rest for 1000 hours under a high-temperature and high-humidity environment of a temperature of +85° C. and a relative humidity of 85%, the adhesive strength was 11.8 N/mm² when it was measured in the same manner. This proved that the heat spreader in the example 1 was also excellent in the resistance to the high-temperature and high-humidity environment.

(Measurement of Adhesion Strength)

The adhesion strength of the Ni plating layer to the base substrate was measured by the following method to which the above-mentioned method of measuring the adhesive strength was applied. That is, two heat spreaders were solder-joined under conditions of 220° C. for three minutes using a Pb—Sn eutectic solder (Pb: 60% by mass, Sn: 40% by mass) in place of the epoxy resin adhesive, to prepare a test piece. A breaking stress exceeded 100N/mm², which was a measurement limit of the Autograph, when it was measured in the same manner as described above. Therefore, it was confirmed that the Ni plating layer firmly adhered to the base substrate.

### Comparative Example 1

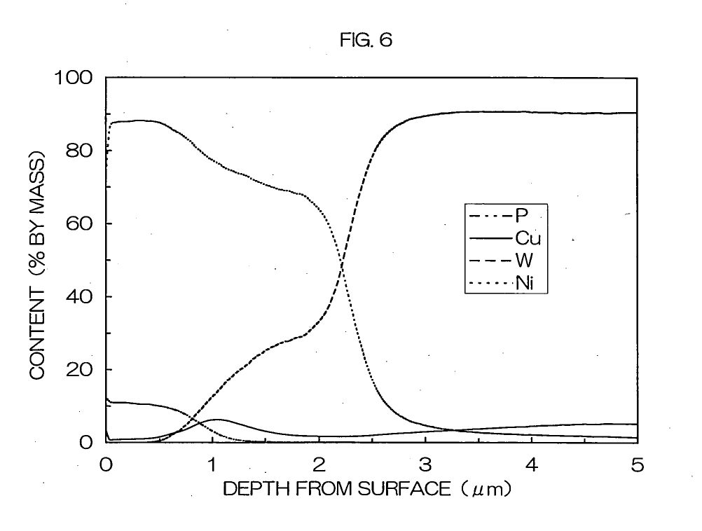

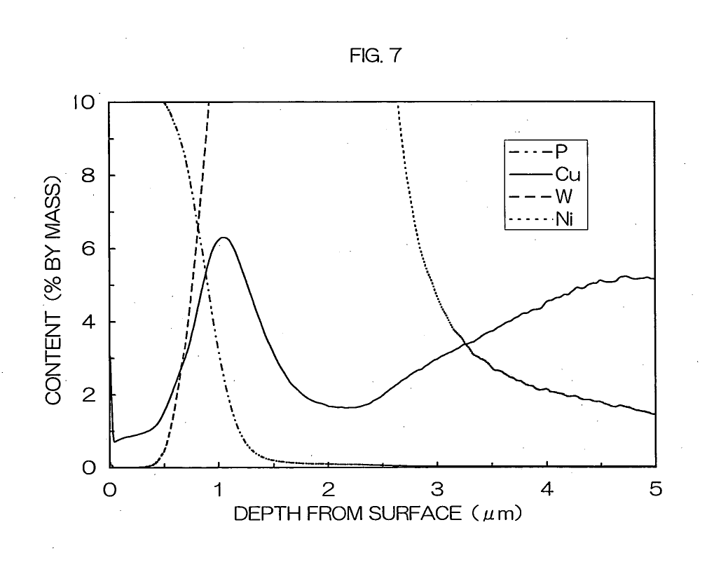

A heat spreader was manufactured in the same manner as in the example 1 except that the heat-treatment temperature of a second plating layer was set to 800° C. The distribution of the content of each of elements such as Cu in the thickness direction was measured in the same manner as that in the example 1, for a Ni plating layer in the heat spreader. The results are shown in FIG. 6. FIG. 7 illustrates the distribution curve of Cu in distribution curves shown in FIG. 6 in enlarged fashion. Although it was confirmed from FIGS. 6 and 7 that in an Ni plating layer, a range of 1.8 μm in the thickness direction from an interface with a base substrate toward its foremost surface was a high Cu region where the content R_{H} (% by mass) of Cu was within the range expressed by the equation (1) and the maximum content of Cu was 6.3% by mass, it was also proved that a large amount of Cu was diffused to the foremost surface of the Ni plating layer, and the content R_{S} (% by mass) of Cu on the foremost surface of the Ni plating layer was as high as 0.8% by mass, and that a low Cu region was not formed.

As to the above-mentioned heat spreader, the adhesion strength of the Ni plating layer exceeded 100 N/mm², which was a measurement limit of the Autograph, when it was measured in the same manner as in the example 1. Therefore, it was confirmed that the Ni plating layer firmly adhered to the base substrate. Further, the adhesive strength was 16.7 N/mm² at the beginning when it was found in the same manner as that in the example 1. Therefore, it was confirmed that the heat spreader in the comparative example 1 was excellent in the connection strength to a another member. However, the adhesive strength of the heat spreader was greatly reduced to 2.9 N/mm² after it was left at rest under a high-temperature and high-humidity environment, which proved that the resistance to the high-temperature and high-humidity environment was insufficient.

### Example 2

### Comparative Examples 2 and 3

Heat spreaders were manufactured in the same manner as that in the example 1 except that the thickness of a first plating layer was 0.05 μm (comparative example 2), 0.2 μm (example 2), and 2.1 μm (comparative example 3).

### Examples 3 and 4

### Comparative Example 4

Heat spreaders were manufactured in the same manner as that in the example 1 except that the thickness of a second plating layer was 0.3 μm (comparative example 4), 0.6 μm (example 3), and 2.5 μm (example 4).

### Examples 5

### Comparative Examples 5 and 6

Heat spreaders were manufactured in the same manner as that in the example 1 except that the heat-treatment temperature T₁ (° C.) of a first plating layer was 500° C. (comparative example 5), 620° C. (example 5), and 900° C. (comparative example 6).

### Example 6

A heat spreader was manufactured in the same manner as that in the example 1 except that the heat-treatment temperature T₁ (° C.) of a first plating layer was 850° C., the thickness of a second plating layer was 2.5 μm, and the heat-treatment temperature T₂ (° C.) of the second plating layer was 580° C.

### Examples 7 to 9

### Comparative Examples 7 to 10

Heat spreaders were manufactured in the same manner as that in the example 1 except that the heat-treatment temperature T₂ (° C.) of a second plating layer was 250° C. (comparative example 7), 280° C. (comparative example 8), 300° C. (example 7), 350° C. (example 8), 550° C. (example 9), 620° C. (comparative example 9), and 700° C. (comparative example 10).

### Example 10

A heat spreader was manufactured in the same manner as that in the example 1 except that a second plating layer was formed by Ni electroplating.

### Example 11

A heat spreader was manufactured in the same manner as that in the example 1 except that both first and second plating layers were formed by electroless Ni—B plating.

### Example 12

A heat spreader was manufactured in the same manner as that in the example 1 except that a base substrate composed of a Cu—Mo composite material produced through the following steps was used.

(Production of Base Substrate)

1% by mass of an acrylic binder was added to Mo powder having an average particle diameter of 3 μm, to granulate the powder to obtain a granulated body having an average particle diameter of 50 μm. A recess, whose plane shape was a rectangle having dimensions of 30 mm in width by 110 mm in length, of a metal mold was filled with the granulated body, and the granulated body was press-molded to the shape of a rectangular plane under a surface pressure of 1.5 ton/cm², and was then heated for one hour at a temperature of 800° C. in a hydrogen gas atmosphere to remove the binder, and was then successively heated to 1250° C. in the hydrogen gas atmosphere and was sintered, to produce a porous body composed of Mo.

The porous body was then heated to 1250° C. in the hydrogen gas atmosphere with the porous body overlapped with a Cu plate whose volume was 1.3 times of the porosity of the porous body, to dissolve Cu, to infiltrate the Cu into pores of the porous body composed of Mo thereby to obtain a precursor of a base substrate composed of a Cu—Mo composite material (Cu: 15% by mass, Mo: 85% by mass). Two surfaces (connection surfaces), parallel to each other, of a plate of the precursor and four side surfaces thereof crossing the two surfaces were respectively ground, to produce a base substrate in the shape of a rectangular plane having dimensions of 25 mm in width by 100 mm in length by 2 mm in thickness.

### Example 13

A heat spreader was manufactured in the same manner as that in the example 1 except that a base substrate composed of a Cu-diamond composite material produced through the following steps was used.

(Production of Base Substrate)

A mixture obtained by blending diamond particles having an average particle diameter of 15 μm and Cu powder such that the diamond particles accounted for 60% by volume with respect to the total volume of the Cu-diamond composite material was preformed under conditions of a pressure of 2 ton/cm², and was sealed into a capsule composed of molybdenum under vacuum. Then, the capsule was heated while being pressurized for five minutes under conditions of a pressure of 5 GPa and a heating temperature of 1100° C., was then reduced to a temperature of not more than 500° C. with the pressure held and held for thirty minutes, and was then returned to normal temperature and normal pressure, then the capsule was recovered.

Then, a surface of the capsule was ground to remove molybdenum to take out a sintered body, and the sintered body was subjected to electrical discharge machining and cut down to dimensions of 25 mm in width and 50 mm in length, and was surface ground to produce a base substrate in the shape of a rectangular plane having dimensions of 25 mm in width by 50 mm in length by 2 mm in thickness.

### Comparative Example 11

A heat spreader was manufactured in the same manner as that in the example 1 except that a second plating layer was not formed on a heat-treated first plating layer.

As to the heat spreaders in the examples and comparative examples, the distribution of the content of each of elements such as Cu in a Ni plating layer in the thickness direction was obtained in the same manner as that in the example 1, and the adhesion strength of the Ni plating layer to a base substrate, the initial adhesive strength, and the adhesive strength after a high-temperature and high-humidity test were obtained. The results, together with the results in the example 1 and the comparative example 1, are shown in Table 1 and Table 2:

TABLE 1

| | | First plating layer | | | Second plating layer | | |
|---|---|---|---|---|---|---|---|
| | Base | | Thickness | Heat-treatment | | Thickness | Heat-treatment |
| | Substrate | Type | (μm) | temperature (° C.) | Type | (μm) | temperature (° C.) |
| Ex. 1 | Cu—W | Ni | 1.2 | 800 | Ni—P | 1 | 500 |
| C. Ex. 1 | Cu—W | Ni | 1.2 | 800 | Ni—P | 1 | 800 |
| C. Ex. 2 | Cu—W | Ni | 0.05 | 800 | Ni—P | 1 | 500 |
| Ex. 2 | Cu—W | Ni | 0.2 | 800 | Ni—P | 1 | 500 |
| C. Ex. 3 | Cu—W | Ni | 2.1 | 800 | *1 | | |
| C. Ex. 4 | Cu—W | Ni | 1.2 | 800 | Ni—P | 0.3 | 500 |
| Ex. 3 | Cu—W | Ni | 1.2 | 800 | Ni—P | 0.6 | 500 |
| Ex. 4 | Cu—W | Ni | 1.2 | 800 | Ni—P | 2.5 | 500 |
| C. Ex. 5 | Cu—W | Ni | 1.2 | 500 | *1 | | |
| Ex. 5 | Cu—W | Ni | 1.2 | 620 | Ni—P | 1 | 500 |
| Ex. 6 | Cu—W | Ni | 1.2 | 850 | Ni—P | 2.5 | 580 |
| C. Ex. 6 | Cu—W | Ni | 1.2 | 900 | *1 | | |
| C. Ex. 7 | Cu—W | Ni | 1.2 | 800 | Ni—P | 1 | 250 |
| C. Ex. 8 | Cu—W | Ni | 1.2 | 800 | Ni—P | 1 | 280 |
| Ex. 7 | Cu—W | Ni | 1.2 | 800 | Ni—P | 1 | 300 |
| Ex. 8 | Cu—W | Ni | 1.2 | 800 | Ni—P | 1 | 350 |
| Ex. 9 | Cu—W | Ni | 1.2 | 800 | Ni—P | 1 | 550 |
| C. Ex. 9 | Cu—W | Ni | 1.2 | 800 | Ni—P | 1 | 620 |
| C. Ex. 10 | Cu—W | Ni | 1.2 | 800 | Ni—P | 1 | 700 |
| Ex. 10 | Cu—W | Ni | 1.2 | 800 | Ni | 1 | 500 |
| Ex. 11 | Cu—W | Ni—B | 1.2 | 800 | Ni—B | 1 | 500 |
| Ex. 12 | Cu—Mo | Ni | 1.2 | 800 | Ni—P | 1 | 500 |
| Ex. 13 | Cu-Dia | Ni | 1.2 | 800 | Ni—P | 1 | 500 |
| C. Ex. 11 | Cu—W | Ni | 1.2 | 800 | — | — | — |

*1 The second plating layer was not formed because it was blistered when the fist plating layer was heat-treated.

TABLE 2

| | Ni plating layer | | | | | | |
|---|---|---|---|---|---|---|---|
| | High Cu region | | | | | Adhesive | |
| | | Maximum | Low Cu region | Foremost surface | Adhesion | Strength | |
| | Thickness | Cu content | Thickness | Cu content | Strength | (N/mm²) | |
| | (μm) | (% by mass) | (μm) | (% by mass) | (N/mm²) | Initial | *2 |
| Ex. 1 | 1.0 | 4.8 | 1.1 | Less than 0.01 | Exceed 100 | 17.6 | 11.8 |
| C. Ex. 1 | 1.8 | 6.3 | 0 | 0.8 | Exceed 100 | 16.7 | 2.9 |
| C. Ex. 2 | 0 | 0.9 | 0.9 | Less than 0.01 | Not measured because | | |
| | | | | | it was blistered | | |
| Ex. 2 | 0.2 | 2.5 | 0.8 | Less than 0.01 | Exceed 100 | 17.6 | 10.8 |
| C. Ex. 3 | 1.7 | 5.0 | | Not measured | | | |
| C. Ex. 4 | 1.3 | 4.8 | 0 | 0.6 | Exceed 100 | 16.7 | 2.0 |
| Ex. 3 | 1.2 | 4.8 | 0.3 | 0.2 | Exceed 100 | 16.7 | 7.8 |
| Ex. 4 | 1.4 | 4.7 | 2.1 | Less than 0.01 | Exceed 100 | 17.6 | 10.8 |
| C. Ex. 5 | 0 | 0.8 | | Not measured | | | |
| Ex. 5 | 0.7 | 4.3 | 1.1 | Less than 0.01 | Exceed 100 | 17.6 | 11.3 |
| Ex. 6 | 1.9 | 6.8 | 0.4 | 0.3 | Exceed 100 | 16.7 | 7.2 |
| C. Ex. 6 | 1.2 | 7.2 | | Not measured | | | |
| C. Ex. 7 | 1.0 | 4.8 | 1.0 | Less than 0.01 | 25 | 2.9 | — |
| C. Ex. 8 | 0.9 | 4.8 | 1.1 | Less than 0.01 | 85 | 14.2 | 4.8 |
| Ex. 7 | 0.9 | 4.8 | 1.1 | Less than 0.01 | 90 | 16.7 | 7.7 |
| Ex. 8 | 0.9 | 4.8 | 1.1 | Less than 0.01 | Exceed 100 | 16.7 | 8.8 |
| Ex. 9 | 1.0 | 4.9 | 1.0 | Less than 0.01 | Exceed 100 | 16.7 | 9.8 |
| C. Ex. 9 | 1.3 | 5.0 | 0.2 | 0.6 | Exceed 100 | 16.7 | 4.5 |
| C. Ex. 10 | 2.0 | 5.2 | 0 | 0.7 | Exceed 100 | 16.7 | 2.9 |
| Ex. 10 | 1.3 | 5.5 | 0.6 | Less than 0.01 | Exceed 100 | 14.7 | 7.8 |
| Ex. 11 | 1.3 | 4.2 | 0.6 | Less than 0.01 | Exceed 100 | 15.7 | 8.8 |
| Ex. 12 | 1.3 | 4.8 | 0.7 | Less than 0.01 | Exceed 100 | 17.6 | 10.8 |
| Ex. 13 | 1.2 | 4.5 | 0.7 | Less than 0.01 | Exceed 100 | 17.6 | 10.8 |
| C. Ex. 11 | 1.2 | 6.3 | 0 | 6.2 | Exceed 100 | 13.7 | 2.0 |

*2 After high temperature and high humidity test

From Tables, the results in the example 1 and the comparative examples 1 and 11 proved that a difference in the distribution of Cu in the Ni plating layer is required, the results in the examples 1 and 2 and the comparative examples 2 and 3 proved that the thickness of the high Cu region defined by the thickness of the first plating layer is preferably not more than 2 μm, and particularly not less than 0.1 μm and not more than 2 μm, and the results in the examples 1, 3 and 4 and the comparative example 4 proved that the thickness of the low Cu region defined by the thickness of the second plating layer is preferably not less than 0.3 μm.

The results in the examples 1, 5, and 6 and the comparative examples 5 and 6 proved that the heat-treatment temperature of the first plating layer has to be more than 600° C. and not more than 850° C., and the results in the examples 1 and 7 to 9 and the comparative examples 7 to 10 proved that the heat-treatment temperature of the second plating layer has to be not less than 300° C. and not more than 600° C. Furthermore, the results in the examples 1 to 9 and the comparative examples 1, 4, 9, and 10 proved that the content of Cu in the foremost surface of the Ni plating layer has to be less than 0.5% by mass.

Furthermore, the results in the examples 1, 10, and 11 proved that the first plating layer is preferably formed by Ni electroplating and the second plating layer is preferably formed by electroless Ni—P plating, and the results in the examples 1, 12, and 13 proved that the base substrate is preferably formed of the Cu—W composite material.

### Example 14

### Production of Base Substrate

1% by mass of an acrylic binder was added to W powder having an average particle diameter of 3 μm, to granulate the powder to obtain a granulated body having an average particle diameter of 50 μm. A recess, whose plane shape was a rectangle having dimensions of 35 mm in length by 35 mm in width, of a metal mold was filled with the granulated body, and the granulated body was press-molded to the shape of a rectangular plane under a surface pressure of 1.5 ton/cm², and was then heated for one hour at a temperature of 800° C. in a hydrogen gas atmosphere to remove the binder, and was then successively heated to 1250° C. in the hydrogen gas atmosphere and was sintered, to produce a porous body composed of W.

The porous body was then heated to 1250° C. in the hydrogen gas atmosphere, with the porous body overlapped with a Cu plate whose volume was 1.3 times of the porosity of the porous body, to dissolve Cu, thereby to infiltrate the Cu into pores of the porous body composed of W to obtain a precursor of a base substrate composed of a Cu—W composite material (Cu: 10% by mass, W: 90% by mass). Two surfaces (connection surfaces), parallel to each other, of a plate of the precursor and four side surfaces thereof crossing the two surfaces were respectively ground, to have the shape of a rectangular plane having dimensions of 30 mm in length by 30 mm in width by 1 mm in thickness. A recess, whose plane shape was a rectangle having dimensions of 19 mm in length by 19 mm in width by 0.25 mm in depth, was formed by counter boring on one surface of the plane by machining, to produce a base substrate 1 having the shape of a plane as shown in FIG. 2 and having a recess 14 provided at its center on a surface 13 of the plane on the lower side in the drawing.

(Production of Heat Spreader)

After a first plating layer having a thickness of 1.2 μm was formed by electro-Ni plating on the whole surface of the base substrate 1, and was heated to 800° C. in a hydrogen gas atmosphere and heat-treated, a second plating layer having a thickness of 1 μm was formed by electroless Ni—P plating on the first plating layer, and was heated to 500° C. in a hydrogen gas atmosphere and heat-treated to form an Ni plating layer 3, thereby to manufacture a heat spreader 4 in which the distribution of the content of Cu was the same as that in the example 1.

(Manufacture of Semiconductor Device)

A silicon-based semiconductor element 12 having dimensions of 15 mm in length by 15 in width by 0.2 mm in thickness was connected through a solder bump 11 to the center on a surface 10 (on the upper side in FIG. 2) of a package 9 made of alumina having dimensions of 30 mm in length by 30 mm in width by 1 mm in thickness, and was heated for one hour at a temperature of 150° C., with layers made of liquid epoxy resin adhesive including 15% by mass of an Ag filler respectively sandwiched between a surface (on the upper side in the drawing) of the semiconductor element 12 and an Ni plating layer 3 on a bottom surface 15 of the recess 14 in the heat spreader 4 serving as a connection surface 2 and between the surface 10 (on the upper side in the drawing) of the package 9 and the Ni plating layer 3 on a surface 13 surrounding the recess 14 in the heat spreader 4 serving as a connection surface 2, to cure the adhesives, thereby to produce a semiconductor device 8 shown in FIG. 2.

(Measurement of Adhesive Strength)

A circular jig whose adhesive surface has a diameter of 10 mm was prepared in order to measure adhesive strength. The above-mentioned semiconductor device 8 was left at rest for 1000 hours under a high-temperature and high-humidity environment of a temperature of +85° C. and a relative humidity of 85%, and was heated for one hour at a temperature of 150° C., while adhesive surfaces of the jigs, described above, were superimposed on the center of a surface 23 (on the lower side in FIG. 2) of the package 9 and on the Ni plating layer 3 at the center of a surface 24 (on the upper side in FIG. 2) of the base substrate 1 with the same layer made of epoxy resin adhesive as that used in the manufacture of the semiconductor device sandwiched therebetween, to cure the adhesives, thereby to respectively adhere the jigs to the respective surfaces.

When the pair of jigs was pulled in upward and downward directions in FIG. 2 to measure the transition of tensile strength thereof, the transition of the tensile strength was changed at the time point where the tensile strength was 4.9 N/mm². However, no peeling or the like was apparently observed between the package 9 and the heat spreader 4. Therefore the measurement was stopped to disassemble the semiconductor device 8 and check the inside thereof. Then, no peeling or the like was observed between the semiconductor element 12 and the heat spreader 4 and between the semiconductor element 12 and the package 9, but the semiconductor element 12 itself was damaged.

### Comparative Example 12

A heat spreader 4 in which the distribution of the content of Cu was the same as that in the comparative example 1 was manufactured in the same manner as that in the example 14 except that the heat-treatment temperature of a second plating layer was set to 800° C., and a example 14 except that the heat spreader 4 was employed. When the semiconductor device 8 was left at rest for 1000 hours under a high-temperature and high-humidity environment of a temperature of +85° C. and a relative humidity of 85%, and the transition of tensile strength was then measured in the same manner as that in the example 14, peeling was observed almost simultaneously between the package 9 and the heat spreader 4 and between the semiconductor element 12 and the heat spreader 4 at the time point where the tensile strength was 0.98 N/mm². When peeled surfaces were observed, it was confirmed that epoxy resin adhesive was peeled from the Ni plating layer 3 by corrosion of Cu in the Ni plating layer 3 on either one of the peeled surfaces.

The present application corresponds to Japanese Patent Application No. 2007-145688 filed with the Japan Patent Office on May 31, 2007, Japanese Patent Application No. 2008-121265 filed with the Japan Patent Office on May 7, 2008 and the entire disclosure of this application is incorporated herein by reference.

What is claimed is:

1. A heat spreader comprising:
a base substrate composed of a material containing at least Cu and having a connection surface for connection to a another member; and
a Ni plating layer formed on at least the connection surface of the base substrate,
wherein in a range of not more than 2 μm in a thickness direction from an interface with the base substrate, the Ni plating layer has a high Cu region where a content R_{H} (% by mass) of Cu satisfies the following equation (1):
1% by mass≦R_{H} (1),
a foremost surface of the Ni plating layer does not contain Cu, or a content R_{S} (% by mass) of Cu in the foremost surface satisfies the following equation (2):
0% by mass<R_{S}<0.5% by mass (2),
and an adhesion strength S_{A} (N/mm²) of the Ni plating layer to the base substrate is not less than 90 N/mm².

2. The heat spreader according to claim 1, wherein
in a range of not less than 0.3 μm in the thickness direction from the foremost surface, the Ni plating layer has a low Cu region where Cu is not contained, or a content R_{L} (% by mass) of Cu satisfies the following equation (3):
0% by mass<R_{L}<0.5% by mass (3).

3. The heat spreader according to claim 1, wherein
the thickness of the high Cu region is not less than 0.1 μm and not more than 2 μm.

4. The heat spreader according to claim 1, wherein
the base substrate is composed of a Cu—W composite material, and
a content of W in the Cu—W composite material is not less than 75% by mass and not more than 95% by mass.

5. A semiconductor device comprising:
a semiconductor element; and
the heat spreader according to claim 1 for removing heat generated when the semiconductor element is operated.

6. The semiconductor device according to claim 5, wherein
the heat spreader has a plurality of connection surfaces, and
the semiconductor element is connected to at least one of the connection surfaces and heat removal member is connected to another connection surfaces through resin adhesive containing Ag fillers respectively.

7. The semiconductor device according to claim 6, wherein
the respective adhesive strengths S_{B} (N/mm²) of the semiconductor element and the heat removal member to the connection surfaces of the heat spreader are not less than 15 N/mm².

8. A method for manufacturing the heat spreader of claim 1, comprising the steps of:
subjecting at least the connection surface of a base substrate composed of a material containing at least Cu to Ni plating to form a first plating layer, and heat-treating the first plating layer at a temperature T₁ (° C.) satisfying the following equation (4) to diffuse Cu into the first plating layer from the base substrate:
600° C.<T₁≦850° C. (4);
and subjecting a surface of the first plating layer to Ni plating to form a second plating layer, and heat-treating the second plating layer at a temperature T₂ (° C.) satisfying the following equation (5) to integrate the second plating layer and the first plating layer to form a Ni plating layer:
300° C.≦T₂≦600° C. (5).
